(19) United States
(12) Patent Application Publication
(10) Pub. No.: US 2013/0061113 A1
(43) Pub. Date: Mar. 7, 2013

(54) METHOD OF CORRECTING ERRORS AND MEMORY DEVICE USING THE SAME

(71) Applicants: Kwan-Ho KIM, Suwon-si (KR); Seung-Hyun SONG, Suwon-si (KR)

(72) Inventors: Kwan-Ho KIM, Suwon-si (KR); Seung-Hyun SONG, Suwon-si (KR)

(73) Assignee: SAMSUNG ELECTRONICS CO., LTD., Suwon-si (KR)

(21) Appl. No.: 13/599,467

(22) Filed: Aug. 30, 2012

(30) Foreign Application Priority Data
Sep. 7, 2011 (KR) 10-2011-0090517

(51) Int. Cl. H03M 13/29; G06F 11/10

(52) U.S. Cl. 714/758; 714/E11.032

(57) ABSTRACT

A method of correcting errors includes receiving a codeword including main data and parity data stored in a memory cell array to perform an error check and correction (ECC) decoding on the codeword and selectively performing an error correction on the codeword based on a result of the ECC decoding using asymmetry of error occurrence of the main data.

### CROSS-REFERENCE TO RELATED APPLICATIONS

This application claims priority under 35 USC §119 from Korean Patent Application No. 10-2011-0090517, filed on Sep. 7, 2011 in the Korean Intellectual Property Office (KIPO), the contents of which are herein incorporated by reference in its entirety.

### BACKGROUND

1. Technical Field

Apparatuses and methods consistent with exemplary embodiments relate to error corrections, and more particularly to a method of correcting errors and a memory device using the same.

2. Description of the Related Art

Generally, semiconductor memory devices can be roughly divided into two categories based on whether or not they retain stored data when disconnected from power. These categories include nonvolatile memory devices, which retain stored data when disconnected from power, and volatile memory devices, which lose stored data when disconnected from power. Accordingly, the nonvolatile memory devices are generally used for storing data regardless of applying power. The non-volatile memory devices may include a mask read-only memory (MROM), a programmable read-only memory (PROM), an erasable programmable read-only memory (EPROM), an electrically erasable programmable read-only memory (EEPROM), a flash memory, etc.

### SUMMARY

Aspects of exemplary embodiments provide a method of correcting errors, capable of increasing error correction capability without increasing parity bits.

Some exemplary embodiments provide a memory device using the method of correcting errors.

According to some exemplary embodiments, a method of correcting errors includes receiving a codeword including main data and parity data, the codeword stored in a memory cell array, to perform an error check and correction (ECC) decoding on the codeword, and selectively performing an error correction on the codeword based on a result of the ECC decoding using asymmetry of error occurrence of the main data.

The method may further include reporting whether the selectively performed error correction on the codeword is successful.

In some embodiments, the error correction on the codeword may be performed within a predetermined maximum repetition number.

In some embodiments, selectively performing an error correction on the codeword may include copying a first block including errors to a second block when the main data includes the errors exceeding an error correction capability; erasing the first block including the errors to write a first data in the erased first block to form third block; detecting first bit positions where a second data different from the first data is read from the first block before being erased; comparing second bit positions where the second data are read in the first block before being erased with the first bit positions in the third block; increasing a repetition number while writing the first data in at least some parts of the first bit positions matching with the second bit positions; performing the ECC decoding on the third block where the first data is written in at least some parts of the first bit positions; and determining whether the error correction is successful by the ECC decoding.

The increasing, the performing, and the determining may be repeated within the predetermined maximum repetition number when the error correction is determined not to be successful.

The ECC decoding may be reported as not successful when the error correction is determined not to be successful within the predetermined maximum repetition number.

The ECC decoding may be reported as successful when the when the error correction is determined to be successful within the predetermined maximum repetition number.

The first data may correspond to “0”.

The second data may correspond to “1”.

The first block may be copied to the second block after pages including correctable errors are corrected.

According to some example embodiments, a memory device includes a memory cell array and an error correction circuit. The memory cell array includes a main cell storing main data and a parity cell storing parity data. The error correction circuit receives a codeword including the main data and the parity data and selectively performs an error correction on the codeword using asymmetry of error occurrence of the main data. The error correction circuit may include a detector which detects errors in the main data to generate a detection signal; a correction unit which receives the main data and the parity data to correct the errors in the main data using the parity data in response to the detection signal, and corrects the errors by repeating error correction operation within a predetermined maximum repetition number when the errors in the main data exceeds error correction capability of the correction unit; and a reporting unit which monitors whether the correction unit corrects the errors in the main data within the predetermined maximum repetition number to report the whether the error correction performed on the codeword is successful.

In some embodiments, the reporting unit may report that the error correction on the codeword is successful when the correction unit corrects the errors in the main data within the predetermined maximum repetition number.

In some embodiments, the reporting unit may report that the error correction on the codeword is not successful when the correction unit does not correct the errors in the main data within the predetermined maximum repetition number.

In some embodiments, the main cell may be one of a single bit cell and a multi-bit cell.

Accordingly, when the errors in the main data exceed the error correction capability, the errors are decreased within the error correction capability by using the asymmetry of the error occurrence and the errors are corrected according to example embodiments. Therefore, example embodiments may be applicable to single bit cell or multi-bit cell because the error correction is performed using the physical features of the storage device.

### BRIEF DESCRIPTION OF THE DRAWINGS

Illustrative, non-limiting exemplary embodiments will be more clearly understood from the following detailed description taken in conjunction with the accompanying drawings.

FIG. 1 is a flow chart illustrating a method of correcting errors according to some exemplary embodiments.

FIG. 2 is a flow chart illustrating the operation (S200) in FIG. 1 in detail according to some exemplary embodiments.

FIG. 3 is a block diagram illustrating a memory device according to some exemplary embodiments.

FIG. 4 is a block diagram illustrating an example of a memory cell array in the memory device of FIG. 3 according to some exemplary embodiments.

FIG. 5 is a graph illustrating a distribution of threshold voltages of a memory cell storing single bit data.

FIG. 6 is a graph illustrating cell threshold voltage distributions in a 2-bit multi-bit cell memory.

FIGS. 7A and 7B illustrate programming process in the 2-bit memory cell.

FIG. 8 schematically illustrates the “PAIRED PAGE” between the LSB page and the MSB page in the 2-bit cell memory.

FIG. 9 is an example of a “PAIRED PAGE,” for example, the “PAIRED PAGE” of FIG. 8.

FIG. 10 illustrates locations of LSB parity pages in a “PAIRED PAGE” for example, the “PAIRED PAGE” of FIG. 9.

FIG. 11 is a block diagram illustrating an example of the error correction circuit in FIG. 3 according to exemplary embodiments.

FIG. 12 is a diagram for describing operation of the ECC decoder in FIG. 11.

FIG. 13 is a block diagram illustrating a memory system including the memory device of FIG. 3.

FIG. 14 is a block diagram illustrating another memory system including the memory device of FIG. 3.

FIG. 15 is a block diagram illustrating a computing system including the memory system of FIG. 13.

### DETAILED DESCRIPTION OF THE EXEMPLARY EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this disclosure will be thorough, and will convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

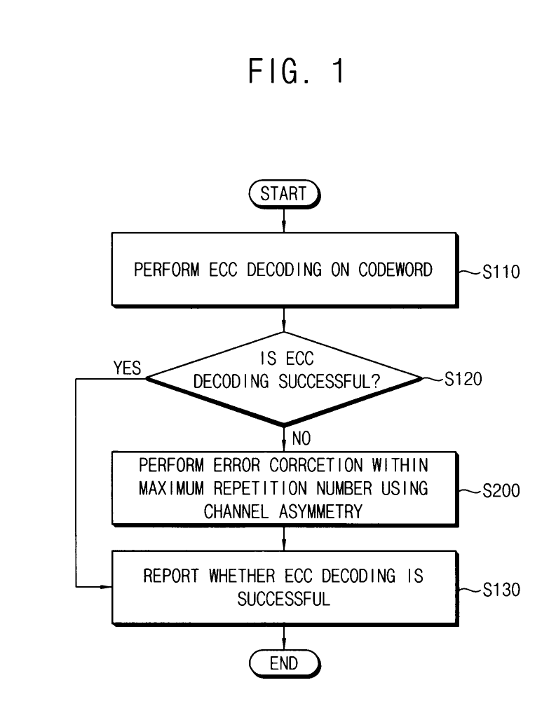

FIG. 1 is a flow chart illustrating a method of correcting errors according to some exemplary embodiments.

Referring to FIG. 1, in a method of correcting errors, a codeword including main data and parity data stored in a memory cell is received and an error check and correction (ECC) decoding is performed on the received codeword (S110). When data is stored in a memory cell, a main data corresponding to user data and write parity data (or error correction code) associated with the main data are stored in the memory cell. The main data and the write parity data are referred to as the codeword. An ECC encoder may store the codeword in the memory cell. When the data is read from the memory cell, the codeword is received, read parity data is generated from codeword, and it is determined whether the main data include errors by comparing the read parity data with the write parity data.

It is then determined whether the errors in the main data are within error correction capability (S120). Determining if error correction on the codeword is within the error correction capability is based on determining if the errors in the main data are within the error correction capability. For example, when the error correction capability is 10 bits, the ECC decoding is successful (YES in S120) when the errors in the main data are not more than 10 bits after the ECC decoding is performed on the received codeword. For example, when the error correction capability is 10 bits, the ECC decoding is not successful (NO in S120) when the errors in the main data are more than 10 bits after the ECC decoding is performed on the received codeword. When the errors in the main data exceed 10 bits, it is possible to detect the errors by the ECC decoding, however it is impossible to correct all errors.

If errors in the main data exceed the error correction capability (NO in S120), exemplary embodiments of the present disclosure take advantage of characteristics of the storage medium to reduce the errors in the main data in an effort to bring the main data with the error correction capability.

The first relevant characteristic is that storage medium such as flash memories may store data by programming a cell having “1” (default state) to a cell having “0”. Therefore, when data is to be written in the flash memory, erase operation must be performed for resetting all data in a block to “1”. As a result, in the flash memory, a first type of error where data which is programmed to “0” is read as “1” is more frequent than a second type of error where data which is programmed to “1” is read as “0”. The difference of the frequency between the first and second types of error may be referred to as asymmetry of error occurrence of the main data.

In addition, in the storage medium as flash memories, it is more probable that errors re-occur in the same cells where errors have occurred in the past rather than new errors occurring in cells where errors have never occurred. That is, the flash memories have physical features causing asymmetry of the error occurrence and error repetition in the same place. Accordingly, when data including more “1” are rapidly changed to data including more “0”, the codeword may include errors exceeding the error correction capability.

Referring back to FIG. 1, if errors in the main data exceed the error correction capability (NO in S120), an error correction on the codeword is selectively performed by using asymmetry of error occurrence of the main data (S200). It may be reported that whether the error correction on the codeword is successful or not (S130).

In the related error correction method, the errors exceeding the error correction capability are detected but are not capable of being corrected. Therefore, the data including the errors exceeding the error correction capability are abandoned. However, even when the data includes the errors exceeding the error correction capability, the errors exceeding the error correction capability may be decreased within the error correction capability by using the asymmetry of the error occurrence of the main data.

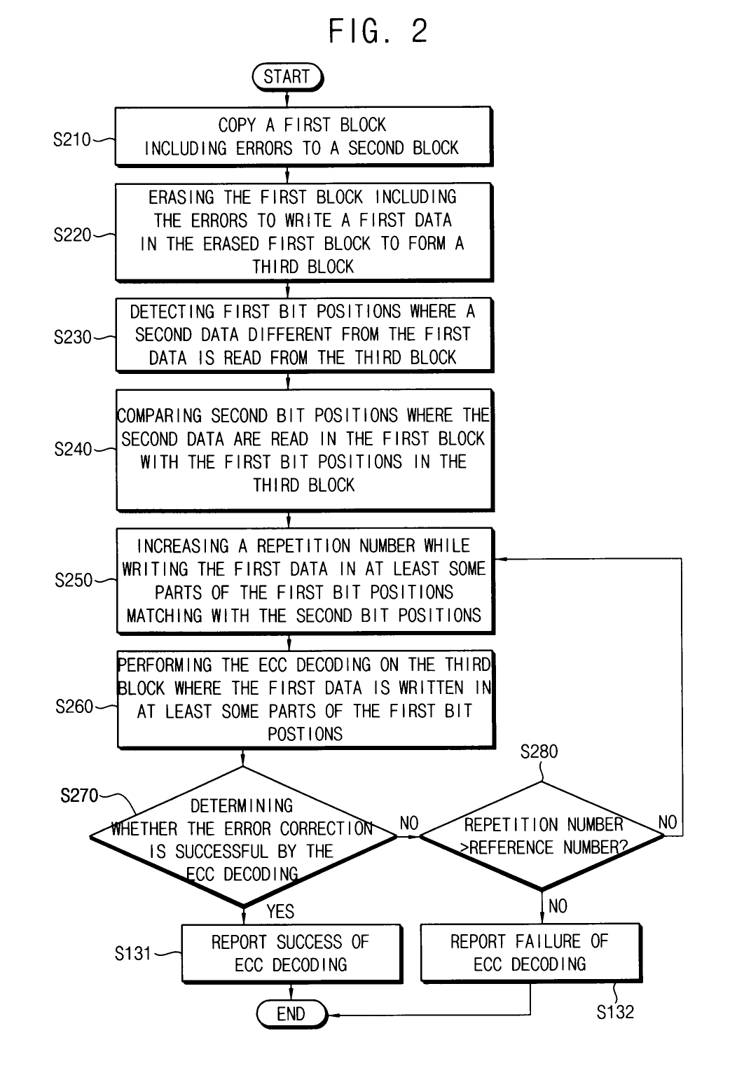

FIG. 2 is a flow chart illustrating the operation (S200) in FIG. 1 in detail according to some exemplary embodiments.

Referring to FIG. 2, for selectively performing the error correction on the codeword, a first block including the errors is copied to a second block which is a free block (S210). Before the data from the first block is written to the second block, correctable pages may be corrected and uncorrectable pages are not corrected. Therefore, the second block may include fewer errors than the first block. The first block is then erased (for example, all cells are set to “1,” which is the default state for some storage medium such as some flash memories), and a first data (for example, “0”) is programmed (written) in all cells of the erased first block to create a third block (S220). The third block is then read to determine if any of the cells in the third block contain second data (for example, “1”) (5230).

If, as described in the above example, all cells in the third block were erased (set to “1”) and then set to “0,” bit positions in the third block found to still contain a “1” may be stuck at “1.” First bit positions where the first data (for instance, “0”) are written but the second data (for instance, “1” is read may be referred to as stuck at fault “1” (SAF1). Second bit positions where the second data (for instance, “1” are read in the first block before being erased are compared with the first bit positions in the third block (S240).

At 5250, first data (for instance, “0”) is written in at least some parts of the first bit positions matching with the second bit positions and a repetition number is increased. Then ECC decoding is performed on the third block where the first data is written in at least some parts of the first bit positions (S260). Then it is determined whether the error correction is successful by the ECC decoding performed on the third block (S270). When the error correction is successful (YES in S270), the ECC decoding is reported as successful (S131). When the error correction is not successful (NO in S270) and the repetition number is below the predetermined maximum number (NO in S280), the operations (S240, 5250 and 5260) are repeated. When the operations (S240, 5250 and 5260) are repeated, some of the first bit positions are changed in the operation (S240). When the error correction is not successful (NO in S270) and the repetition number exceeds the predetermined maximum number (or reference number) (NO in S280), the ECC decoding is reported as not successful (S132).

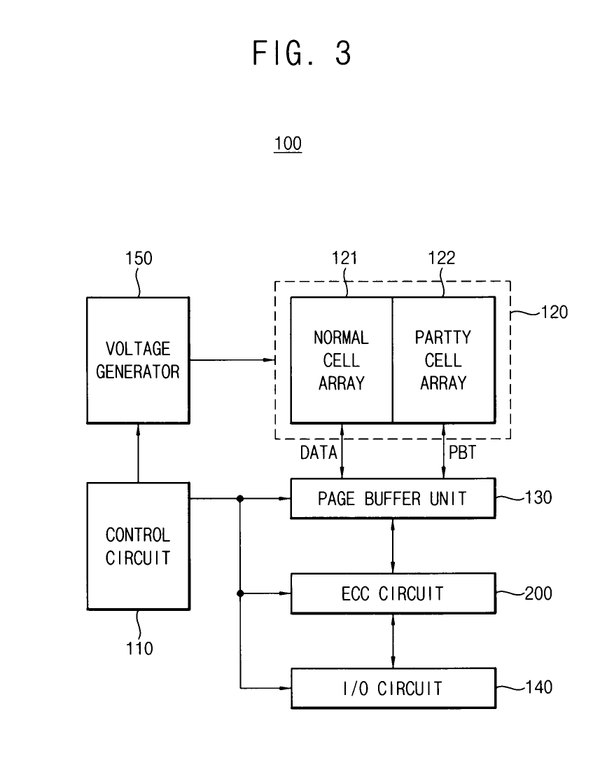

The method of correcting errors with reference to FIGS. 1 and 2 will be described in detail with reference to FIGS. 3 through 9.

FIG. 3 is a block diagram illustrating a memory device according to some example embodiments.

Referring to FIG. 3, a memory device 100 includes a control circuit 110, a memory cell array 120, a page buffer unit 130, an error correction circuit 200, and an input/output (I/O) circuit 140, and a voltage generator 150.

The memory cell array 120 may include a main cell 121 storing a main data DATA and a parity cell 122 including a parity data PBT. The main cell 121 and the parity cell 122 are connected to wordlines and bitlines. A page, which is a unit of read operation, may include the main cell 121 and the parity cell 122, and a codeword including the main data and the parity data is read from the page. The parity data PBT may be an error correction code.

The page buffer unit 130 may operate as a write driver or as a sense amplifier according to an operation mode. For example, the page buffer unit 130 operates as a sense amplifier in a read operation mode, and the page buffer unit 130 operates as a write driver in a write operation mode. The page buffer unit 130 may include page buffers which are connected to the bitlines and stores the main data DATA and the parity data PBT temporarily. Each of the page buffers may include a data latch connected to corresponding bitline of the bitlines.

The error correction circuit 200 receives the main data DATA, generates the parity data PBT and provides the main data DATA and the parity data PBT to the memory cell array 120 via the page buffer unit 130 in the write operation mode. In addition, the error correction circuit 200 receives the codeword including the main data DATA and the parity data PBT stored in the memory cell array 120 and may perform an error correction on the codeword by using the asymmetry of the error occurrence of the main data DATA. The error correction circuit 200 may be included in the memory device 100 as illustrated in FIG. 3 or may be external to the memory device 100 in some embodiments. For example, the error correction circuit 200 may be included in a memory controller.

The I/O circuit 140 may provide the memory cell array 120 with external input data or provide output data from the memory cell array 120 externally under control of the control circuit 110.

The voltage generator 150 generates a program voltage for programming, a pass voltage, a verify voltage, and a read voltage under control of the control circuit 110. For example, the voltage generator 150 provides the program voltage to a selected wordline and provides the pass voltage to unselected wordlines in a program operation mode under control of the control circuit 110. In addition, the voltage generator 150 provides the ground voltage to a selected wordline and provides the read voltage to unselected wordlines in a read operation mode under control of the control circuit 110.

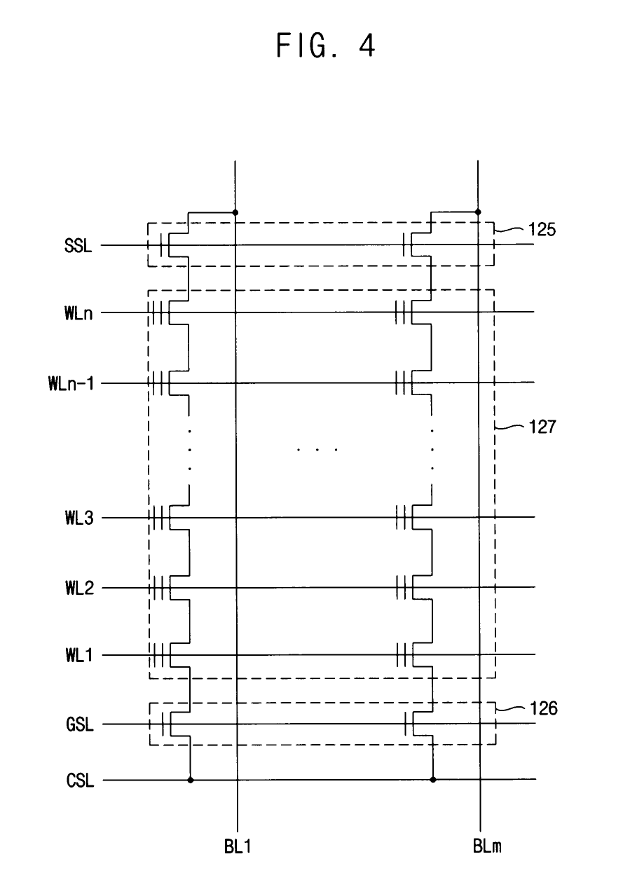

FIG. 4 is a block diagram illustrating an example of a memory cell array in the memory device of FIG. 3 according to some example embodiments.

Referring to FIG. 4, a memory cell array 120 may include string selection transistors 125, ground selection transistors 126 and memory cells 127.

The string selection transistors 125 may be connected to bitlines BL1, . . . , BLm and the ground selection transistors 126 may be connected to a common source line (CSL). The memory cells 127 may be connected in series between the respective string selection transistors 125 and the respective ground selection transistors 126. Memory cells may be arranged in a matrix form of rows and columns, and memory cells located in the same row may also share a corresponding wordline among wordlines WL1, WL2, WL3, . . . , WLn−1, WLn. The string selection transistors 125 may be controlled using voltages applied via a string selection line (SSL), and the ground selection transistors 126 may be controlled using voltages applied via a ground selection line (CSL). The memory cells 127 may be controlled using voltages applied via the respective wordlines WL1, WL2, WL3, . . . , WLn−1, WLn. Some of the memory cells 127 may correspond to the main cell 121 in FIG. 3, and some of the memory cells 127 may correspond to the parity cell 122 in FIG. 3. Each of the memory cells 127 may store single bit data or multi-bit data.

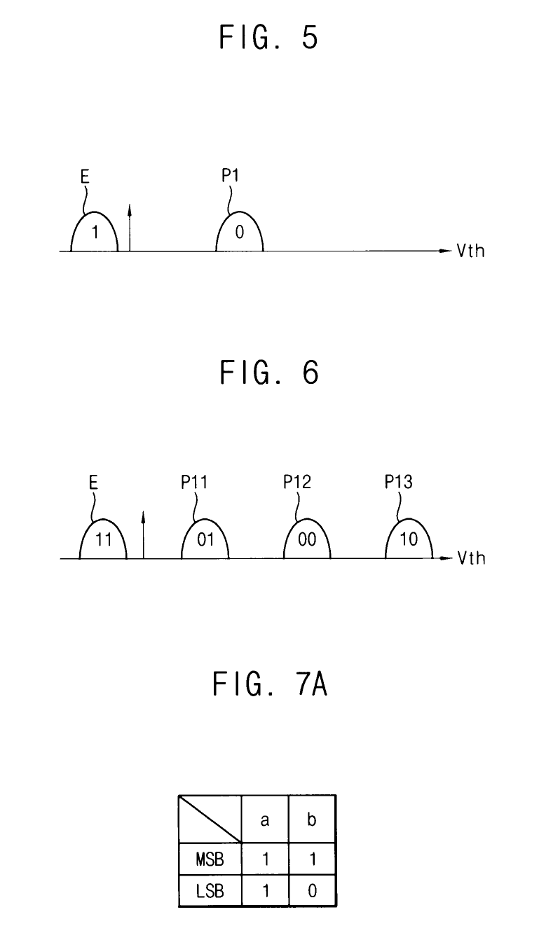

FIG. 5 is a graph illustrating a distribution of threshold voltages of a memory cell storing single bit data.

In FIG. 5, x axis denotes a threshold voltage (Vth) and y axis denotes cell numbers.

Referring to FIG. 5, the single bit cells may have an erased state E and a first programmed state P1. The single bit cells may have the erased state E as a default state, and the single bit cell having the erased state E may have the first programmed state P1 by applying a program voltage. The first programmed state P1 may correspond to “0” (first data) and the erased state E may correspond to “1” (second data). Therefore, in the single bit cells, a first type of error where date which is programmed to “0” is read as “1” is more frequent than a second type of error where data which is programmed to “1” is read as “0”. In addition, it is more probable that errors occur in first places where the error occurred than second places where the error did not occur.

FIG. 6 is a graph illustrating cell threshold voltage distributions in a 2-bit multi-bit cell memory.

In FIG. 6, x axis denotes a threshold voltage (Vth) and y axis denotes cell numbers.

Referring to FIG. 6, the multi-bit cells may have an erased state E and first through third programmed states P11, P12 and P13. The erased state E corresponds to “11”, the first programmed state corresponds to “01”, the second programmed state corresponds to “00” and the third programmed state corresponds to “10”. A lower bit of the multi-bit data is referred to as the least significant bit (LSB) and an upper bit of the multi-bit data is referred to as the most significant bit (MSB). In the multi-bit cell memory, at least two program operations are required.

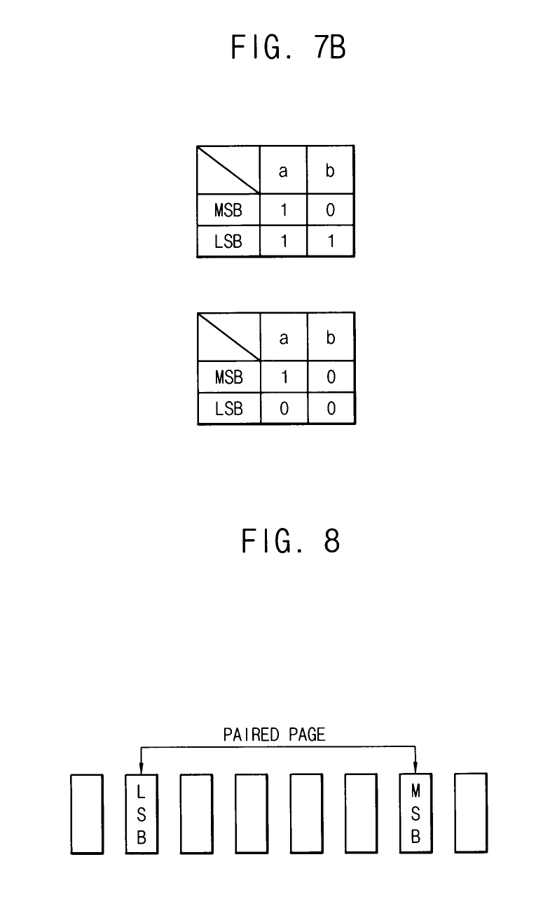

FIGS. 7A and 7B illustrate programming process in the 2-bit memory cell.

Referring to FIG. 7A, the LSB “1” of a memory cell is initialized to “11” (a) is programmed to “0” (b) and thus, the programmed memory cell has a value of “10”. Then, as in FIG. 7B, MSB of a memory cell initialized to “11” (a) is programmed to “0” (b) and then, the programmed memory cell has a value of “01”. In addition, the MSB of a memory cell programmed to “10” (a) is programmed to “0” (b) and then, the programmed memory cell has a value of “00”.

As such, the LSB and the MSB that are programmed to different pages may be connected by a “PAIRED PAGE” as illustrated in FIG. 8.

FIG. 8 schematically illustrates the “PAIRED PAGE” between the LSB page and the MSB page in the 2-bit cell memory.

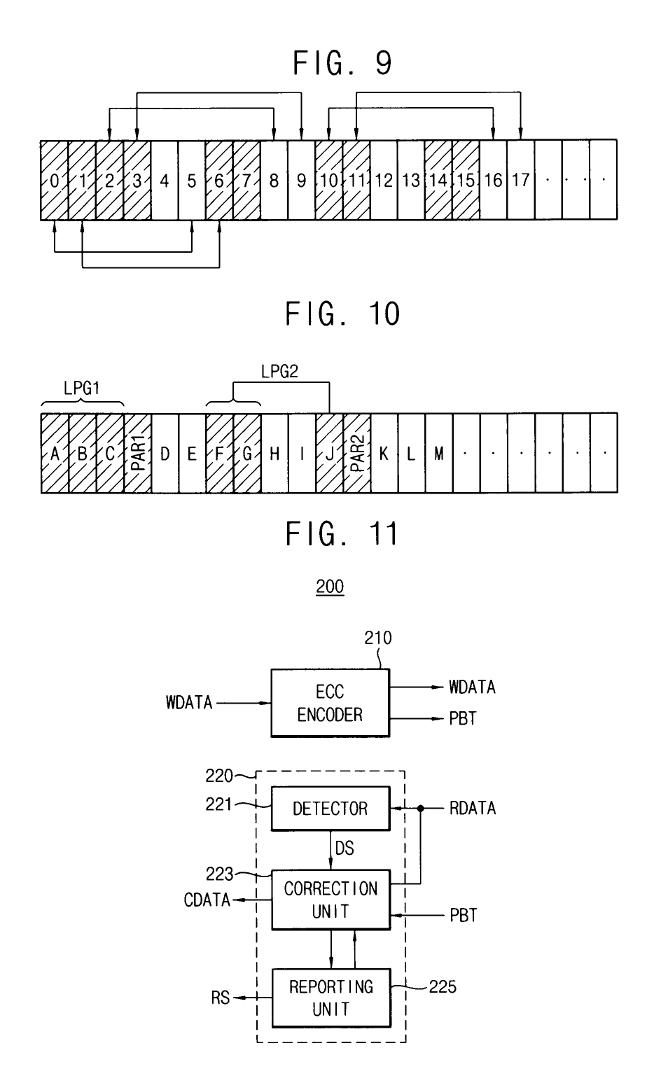

FIG. 9 is an example of a “PAIRED PAGE,” for example, the “PAIRED PAGE” of FIG. 8.

Referring to FIGS. 8 and 9, in the “PAIRED PAGE” of FIG. 8, first two LSB pages 0 and 1 and last two LSB pages (not illustrated) may pair with the MSB pages which are spaced apart from the LSB pages by four pages. The rest of the LSB pages 2, 3, 6, 7 . . . may pair with the MSB pages which are spaced apart from the LSB pages by six pages. For example, the LSB page “0” may pair with the MSB page “4” and the LSB page “2” may pair with the MSB page “8.”

FIG. 10 illustrates locations of LSB parity pages in a “PAIRED PAGE” for example, the “PAIRED PAGE” of FIG. 9.

Referring to FIG. 10, it is assumed that arbitrary numbers of the LSB pages, that are adjacent to each other, are denoted as an LSB page group. Here, a second LSB page group LPG 2 is formed of the LSB page “F” located closest to a first LSB page group LPG 1 and the LSB pages “G” and “J” existing between the LSB page “F” and the MSB page “K”, which pairs with the LSB page “F”.

The LSB parity pages for the LSB pages included in each LSB page group exist. For example, the LSB parity page “PAR 1” exists for the three LSB pages “A”, “B” and “C” included in the first LSB page group LPG 1. Here, the LSB parity page “PAR 1” may be realized using information generating methods used in a method of generating a parity (a Redundant Array of Independent/Inexpensive Disks (RAID) technique), the parity being generated for the three LSB pages “A”, “B” and “C”.

In the 2-bit cell memory, the LSB pages and the MSB pages that are related to each other share the same word line so that when an MSB page has errors, a programmed state of an LSB page is not ensured. That is, in a “PAIRED PAGE” architecture, the errors tend to occur at same places.

According to example embodiments, the error correction may be performed using the physical features of the memory device where the errors tend to occur at same places.

FIG. 11 is a block diagram illustrating an example of the error correction circuit in FIG. 3 according to example embodiments.

Referring to FIG. 11, the error correction circuit 200 may include an ECC encoder 210 and an ECC decoder 220.

The ECC encoder 210 receives the write data WDATA and generates the parity data PBT which is used for error correction based on the write data WDATA. The write data WDATA and the parity data PBT are stored in the memory cell array 120 via the page buffer unit 130 under control of the control circuit 110.

The ECC decoder 220 receives the read data RDATA and the parity data PBT detects errors in the read data RDATA and correct the errors in the read data RDATA using the parity data PBT. The ECC decoder 220 may include a detector 221, a correction unit 223 and a reporting unit 225.

The detector 221 receives the read data RDATA and provides the correction unit 223 with a detection signal DS indicating whether the read data RDATA includes the errors. For example, when the read data RDATA does not include the errors, the detection signal DS may be a first logic level (logic low level). For example, when the read data RDATA includes the errors, the detection signal DS may be a second logic level (logic high level).

The correction unit 223 receives the read data RDATA and the parity data PBT and may correct the errors in the read data RDATA using the parity data PBT. For example, when the RDATA included the errors within error correction capability of the correction unit 223, the correction unit 223 may correct the errors in the read data RDATA immediately. For example, when the RDATA included the errors exceeding the error correction capability of the correction unit 223, the correction unit 223 decreases the errors in the read data RDATA within the error correction capability of the correction unit 223 using the asymmetry of the error occurrence, corrects the errors in the read data RDATA and provides a corrected data CDATA.

The reporting unit 225 monitors whether the correction unit 223 completes the error correction within a predetermined maximum repetition number and provides a reporting signal RS indicating the monitoring result. For example, when the correction unit 223 does not correct the errors in the read data RDATA within predetermined maximum repetition number, the reporting unit 225 outputs the reporting signal RS with a first logic level (logic low level). For example, when the correction unit 223 corrects the errors in the read data RDATA within predetermined maximum repetition number (complete the error correction), the reporting unit 225 outputs the reporting signal RS with a second logic level (logic high level).

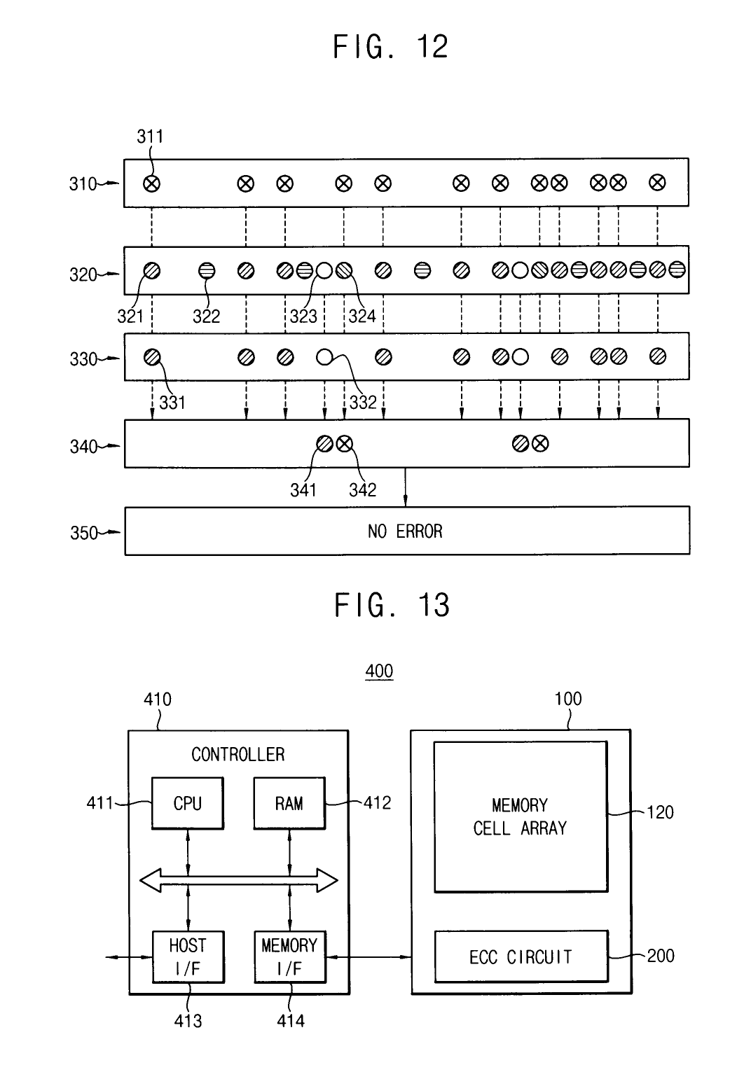

FIG. 12 is a diagram for describing operation of the ECC decoder in FIG. 11.

It is assumed for this example that the ECC decoder 220 (the correction unit 223) has an error correction capability of 10 bits.

Referring to FIG. 12, a block 310 (a first block) includes errors exceeding the error correction capability of the correction unit 223. Reference numerals 311 indicate bit positions of errors in the block 310. User may know that the errors occur in the block 310 and the number of the errors but may not know the positions where the errors occur. Since the block 310 includes the errors exceeding the error correction capability of the correction unit 223 (in this example, the number of the errors in the block 310 exceeds 10 bits), the ECC decoder may report uncorrectable.

When the block 310 includes the errors exceeding the error correction capability of the correction unit 223, the ECC decoder 200 cannot correct the errors. Therefore, the block 310 is copied to a second block (free block), and the block 310 is erased. Before erasing the block 310, read operation is performed on the block 310. First data (“0”) are written (programmed) in all cells of the erased first block to create a third block, and read operation is performed on the third block. Then, the third block 320 may include cells as illustrated.

A reference numeral 321 represents a bit position where the first data (“0”) is written but a second data (“1”) is read in the block 320. A reference numeral 322 represents a bit position where the first data (“0”) is read. A reference numeral 323 represents a bit position where the first data (“0”) is written but the second data (“1”) is read. The reference numeral 323 corresponds to a bit position where the error does not occur in the block 310, but the “1” is read because the originally written data is “1”. Therefore, the reference numeral 323 indicates a bit position having a possibility of error occurrence. A reference numeral 324 represents a bit position where the first data (“0”) is written and the first data (“0”) is read. The reference numeral 324 corresponds to a bit position where “1” is read in the block 310. Therefore, the reference numeral 324 indicates a bit position having a possibility of error occurrence. That is, the reference numerals 321, 322 and 323 indicates the bit positions where the errors occur after the block 310 is erased and the “0” is written. Therefore, the reference numerals 321, 322 and 323 are referred to as stuck bit position.

When the first bit positions 321, 322 and 323 where the “1” is read in the block 320 and the second bit positions where the “1” is read in the block 310, the comparison result comes to a block 330. A reference numeral 331 represents a bit position where the error occurs both in the blocks 310 and 320, and a reference numeral 332 represents a bit position where the error does not occur in the block 310 but the “1” is read in the block 320 because the originally written data is “1”. That is, the reference numeral 331 represents a bit position where “0” is to be written but the wrong data (“1”) is written, and the reference numeral 332 where the right data (“1”) is written but the “0” is not programmed. Therefore, the reference numerals 331 and 332 may be error position candidates in the block 330.

When the “0” is written in error position candidates in the block 330 overlapping with the bit positions where the errors occur in the block 310, the result comes to a block 340. The error of the bit position 331 in the block 330 is corrected by writing “0” because the bit position 331 is a bit position where “0” is to be written but the wrong data (“1”) is written. A reference numeral 341 represents a bit position where the right data (“1”) is written but “0” is not programmed, and thus the reference numeral 341 corresponds to a new error. The reference numeral 342 indicates the errors are not corrected because the reference numeral 342 is not included in bit positions where the error position candidates 331 and 332 in the block 330 and the error positions 311 in the block 310 are overlapped. The block 340 includes four errors, and the four errors are within the error correction capability of the correction unit 223. Therefore, when the errors in block 340 are corrected, a block 350 including no errors is obtained.

When the “0” is written in bit positions where the error position candidates 331 and 332 in the block 330 and the error positions 311 in the block 310 are overlapped, the “0” is written in some part of the bit positions where the error position candidates 331 and 332 in the block 330 and the error positions 311 in the block 310 are overlapped by considering the error correction capability of the correction unit 223.

As mentioned above, when the errors in the main data exceed the error correction capability, the errors are decreased within the error correction capability by using the asymmetry of the error occurrence and the errors are corrected according to example embodiments. Therefore, example embodiments may be applicable to single bit cell or multi-bit cell because the error correction is performed using the physical features of the storage device.

In addition, the error correction may be performed based on information that the errors tend to occur at same bitline positions in the same block. In addition, the error correction may be performed based on additional information that data corruption position of a page which passes the ECC decoding or the errors tend to occur at the same positions in PAIRED PAGE of the multi-bit cell.

FIG. 13 is a block diagram illustrating a memory system including the memory device of FIG. 3.

Referring to FIG. 13, a memory system 400 includes a memory device 100 and a memory controller 410.

The memory device 100 may include a memory cell array 110 and an error correction circuit 200. The memory cell array 110 may include a memory cells connected to bitlines and wordlines. The error correction circuit 200 receives the main data DATA, generates the parity data PBT and provides the main data DATA and the parity data PBT to the memory cell array 120 in the write operation mode. In addition, the error correction circuit 200 receives the codeword including the main data DATA and the parity data PBT stored in the memory cell array 120 and may perform an error correction on the codeword by using the asymmetry of the error occurrence of the main data DATA.

The memory controller 410 controls the memory device 100. The memory controller 410 may control data exchanges between an external host and the memory device 100. The memory controller 410 may include a central processing unit (CPU) 411, a buffer memory (RAM) 412, a host interface (HOST I/F) 413 and a memory interface (MEMORY I/F) 414. The central processing unit 411 may perform operations for the data exchanges. The host interface 413 may be connected to the external host and the memory interface 414 may be connected to the memory device 100. The central processing unit 411 may communicate with the external host via the host interface 413. The central processing unit 411 may control the memory device 100 via the memory interface 411. The memory device 100 may be a flash memory device. In an embodiment, the memory device 100 may be a storage medium which has physical features such as asymmetric error occurrence and error repetitiveness.

In some embodiments, the memory controller 410 may further include a nonvolatile memory device storing a start-up code. The memory controller 410 may further include an error correction block. The buffer memory (RAM) 412 may include dynamic random access memory (DRAM), static random access memory (SRAM), phase change random access memory (PRAM), ferroelectric random access memory (FRAM), resistive random access memory (RRAM), magnetic random access memory (MRAM), etc. The buffer memory (RAM) 412 may provide storage for operations of the central processing unit 411.

The host interface 413 may communicate with external devices such as the external host using various interface protocols such as universal serial bus (USB), multi-media card (MMC), peripheral component interconnect (PCI), serial advanced technology attachment (SATA), parallel advanced technology attachment (PATA), small computer system interface (SCSI), enhanced small disk interface (ESDI), integrated Drive Electronics (IDE), etc.

The memory device 100 and/or the memory controller 410 may be mounted on chip using various packages such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline (SOIC), shrink small outline package (SSOP), thin small outline package (TSOP), system in package (SIP), multi chip package (MCP), wafer-level fabricated package (WFP), wafer-level processed stack package (WSP), etc. According to example embodiments, memory cells of the memory device 100 may be multi level cells (MLC) including charge storing layers and thus may have various cell structures such as charge trap flash (CTF) structure including charge trap layers, stack flash structure in which multiple memory arrays are stacked, flash structure without source and drain, pin type flash structure, etc.

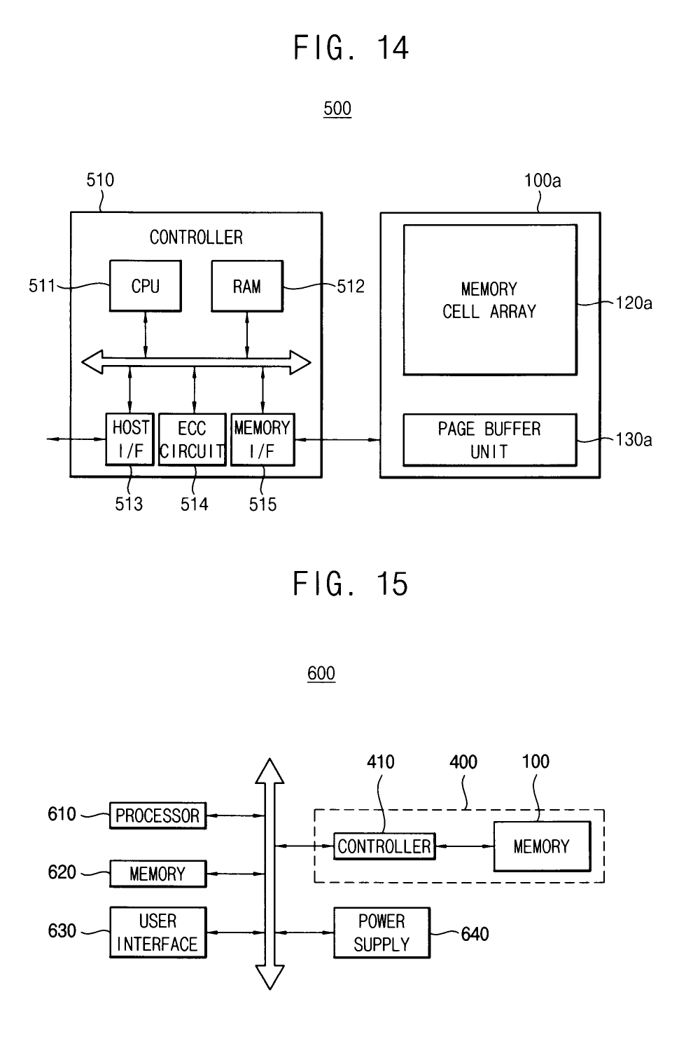

FIG. 14 is a block diagram illustrating another memory system including the memory device of FIG. 3.

Referring to FIG. 14, a memory system 500 includes a memory device 100a and a memory controller 510.

The memory device 100c may include a memory cell array 120a and a page buffer unit 130a. The page buffer unit 130a may include page buffers connected to respective bitlines. The memory cell array 120a may include a plurality of memory cells that are connected to wordlines and the bitlines.

The memory controller 510 controls the flash memory device 100a. The memory controller 510 may control data exchanges between an external host and the memory device 100a. The memory controller 510 may include a central processing unit (CPU) 511, a buffer memory (RAM) 512, a host interface (HOST I/F) 513 a memory interface (MEMORY I/F) 515 and an error correction circuit 514. Since respective Operations of the central processing unit (CPU) 511, the buffer memory 512, the host interface 513 and the memory interface 515 are substantially the same as respective operations of the central processing unit 411, the buffer memory 412, the host interface 413 and the memory interface 414, and thus detailed description on operations of the central processing unit (CPU) 511, the buffer memory 512, the host interface 513 and the memory interface 515 will be omitted. The memory system 500 of FIG. 14 differs from the memory system 400 of FIG. 13 in that the error correction circuit 514 is included in the memory controller 510. The error correction circuit 514 decreases the errors in the read data within the error correction capability and performs the error correction on the read data from the memory cell array 120a using the asymmetry of the error occurrence of the read data even when the errors in the read data exceeds the error correction capability of the error correction circuit 514. The error correction circuit 514 may employ the error correction circuit 200 of FIG. 11.

FIG. 15 is a block diagram illustrating a computing system including the memory system of FIG. 13.

Referring to FIG. 15, a computing system 600 includes a processor 610, a memory device 420, a user interface 430 and a memory system 400.

The processor 610 may perform various computing functions, such as executing specific software for performing specific calculations or tasks. For example, the processor 610 may be a microprocessor or a central process unit (CPU). The processor 610 may be connected to the memory device 620 via bus such as an address bus, a control bus or a data bus, etc. For example, the memory device 620 may be a dynamic random access memory (DRAM), a static random access memory (SRAM), or a non-volatile memory, such as an erasable programmable read-only memory (EPROM), an electrically erasable programmable read-only memory (EEPROM), a flash memory and/or the like. The processor 610 may be connected to an expansion bus, such as peripheral component interconnect (PCI) bus. The processor 610 may control one or more input/output devices, such as a keyboard, a mouse, a printer, a display device, etc. The computing system 600 may further include a storage device, such as a floppy disk drive, a compact disk read-only memory (CD-ROM) drive, a hard disk drive, etc. The processor 610 may control user interface 630, which may comprise, for instance, an input device (e.g., a keyboard or a mouse), an output device (e.g., a printer or a display device) and a storage device (e.g., a hard disk drive or a compact disk read-only memory (CD-ROM)). The memory device 100 may store multi bit data that are provided via the user interface 630 or provided from the processor 610. The computing system 600 may further include a power supply 640 for supplying operational power. The computing system 600 may further include an application chipset, a camera image processor (CIS), and a mobile DRAM.

The computing system 600 according to example embodiments may comprise any of several types of electronic devices, such as a cellular phone, a personal digital assistant (PDA), a digital camera, a portable game console, a MP3 player, a desktop computer, a laptop (or a notebook computer), a digital speaker, a video player, a television, and many others.

Example embodiments may be applicable to any type of storage media which have physical features such as asymmetric error occurrence and error repetitiveness.

The described embodiments may be employed in different type of data storing devices or computing systems that are required to store multi bit data for some purposes. Moreover, the described embodiments may be employed in semiconductor devices such as a flash memory device, a memory card, a solid state drive, a cellular phone, a personal digital assistant (PDA), a digital camera, a portable game console, a MP3 player, a desktop computer, a laptop (or a notebook computer), a digital speaker, a video player, a television, and many others.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of correcting errors, comprising:
receiving a codeword comprising main data and parity data, the codeword stored in a memory cell array, to perform an error check and correction (ECC) decoding on the codeword; and
selectively performing an error correction on the codeword based on a result of the ECC decoding using asymmetry of error occurrence of the main data.

2. The method of correcting errors of claim 1, further comprising:
reporting whether the selectively performed error correction on the codeword is successful.

3. The method of correcting errors of claim 1, wherein the error correction on the codeword is performed within a predetermined maximum repetition number.

4. The method of correcting errors of claim 1, wherein selectively performing the error correction on the codeword comprises:
copying a first block including errors to a second block when the main data includes the errors exceeding an error correction capability;
erasing the first block including the errors to write a first data in the erased first block to form a third block;
detecting first bit positions where a second data different from the first data is read from the first block before being erased;
comparing second bit positions where the second data are read in the first block before being erased with the first bit positions in the third block;
increasing a repetition number while writing the first data in at least some parts of the first bit positions matching with the second bit positions;
performing the ECC decoding on the third block where the first data is written in at least some parts of the first bit positions; and
determining whether the error correction is successful by the ECC decoding.

5. The method of correcting errors of claim 4, wherein the increasing, the performing, and the determining are repeated within a predetermined maximum repetition number when the error correction is determined not to be successful.

6. The method of correcting errors of claim 5, wherein the ECC decoding is reported as not successful when the error correction is determined not to be successful within the predetermined maximum repetition number.

7. The method of correcting errors of claim 5, wherein the ECC decoding is reported as successful when the when the error correction is determined to be successful within the predetermined maximum repetition number.

8. The method of correcting errors of claim 4, wherein the first data corresponds to “0”.

9. The method of correcting errors of claim 4, wherein the second data corresponds to “1”.

10. The method of correcting errors of claim 4, wherein the first block is copied to the second block after pages including correctable errors are corrected.

11. A memory device comprising:
a memory cell array comprising a main cell and a parity cell, the main cell storing main data and the parity cell storing parity data; and
an error correction circuit which receives a codeword including the main data and the parity data and which selectively performs an error correction on the codeword using asymmetry of error occurrence of the main data.

12. The memory device of claim 11, wherein the error correction circuit comprises:
a detector which detects errors in the main data to generate a detection signal;
a correction unit which receives the main data and the parity data to correct the errors in the main data using the parity data in response to the detection signal, and which corrects the errors by repeating error correction operation within a predetermined maximum repetition number when the errors in the main data exceeds error correction capability of the correction unit; and
a reporting unit which monitors whether the correction unit corrects the errors in the main data within the predetermined maximum repetition number to report the whether the error correction performed on the codeword is successful.

13. The memory device of claim 12, wherein the reporting unit reports that the error correction on the codeword is successful when the correction unit corrects the errors in the main data within the predetermined maximum repetition number.

14. The memory device of claim 12, wherein the reporting unit reports that the error correction on the codeword is not successful when the correction unit does not correct the errors in the main data within the predetermined maximum repetition number.

15. The memory device of claim 11, wherein the main cell is one of a single bit cell and a multi-bit cell.

16. An error correction method, comprising:
receiving data comprising one or more errors;
performing error check and correction (ECC) decoding on the received data to form decoded data;
determining whether a number of errors in the decoded data exceeds an error correction capability of the ECC decoding; and
correcting data using asymmetry of error in response to a determination of that the number of errors in the decoded data exceeds the error correction capability of the ECC decoding,
wherein correcting data using asymmetry of error comprises:
copying the decoded data from a first block to a second block,
erasing the first block by writing a “1” in all cells of the first block,
writing a “0” in all cells of the first block to create a third block,
detecting a position of one or more cells in the third block containing a “1”, and
writing a “0” in one or more cells of the second block corresponding to the position in the third block containing a “1”.

17. The method of claim 16, wherein the error correction capability of the ECC decoding comprises the number of errors the ECC decoding is capable of correcting.

18. The method of claim 16, wherein the correcting data using asymmetry of error further comprises repeating the operation of writing “0” in one or more cells of the second block corresponding to positions in the third block containing a “1” until the data in the third block is with the error correction capacity of the ECC decoding.

19. The method of claim 16, wherein the received data comprises main data and parity data.

20. The method of claim 19, wherein the ECC decoding comprises using the parity data to correct errors in the main data.
